(19) United States
(12) Patent Application Publication
(10) Pub. No.: US 2008/0122021 A1
(43) Pub. Date: May 29, 2008

(54) IMAGE SENSOR

(76) Inventor: Jin-Ho Park, Seoul (KR)

Correspondence Address: SHERR & NOURSE, PLLC, 620 HERNDON PARKWAY, SUITE 200, HERNDON, VA, 20170, US

(21) Appl. No.: 11/869,525

(22) Filed: Oct. 9, 2007

(30) Foreign Application Priority Data
Nov. 24, 2006 (KR) 10-2006-0116777

(51) Int. Cl. H01L 31/0232; H01L 31/18

(52) U.S. Cl. 257/432; 438/69; 257/E31.128

(57) ABSTRACT

Embodiments relate to an image sensor and a method of manufacturing the same. In embodiments, an image sensor may include a photodiode structure having a plurality of pixels, aligned on a semiconductor substrate, an inorganic micro-lens group including an inorganic substance, aligned at positions corresponding to a first pixel group in the pixels on the photodiode structure, and an organic micro-lens group including an organic substance, aligned at positions corresponding to a second pixel group except for the inorganic micro-lens group in the pixels on the photodiode structure. In embodiments, the micro-lenses are formed such that there are no gaps between adjacent micro-lenses.

The present application claims priority under 35 U.S.C. 119 and 35 U.S.C. 365 to Korean Patent Application No. 10-2006-0116777 (filed on Nov. 24, 2006), which is hereby incorporated by reference in its entirety.

### BACKGROUND

An image sensor may be a semiconductor device configured to convert optical images into electric signals, and may be classified into one of a charge coupled device (CCD) and a CMOS image sensor.

A related art image sensor may be manufactured through the following processes.

First, transistors and photodiodes electrically connected to the transistors may be formed on a semiconductor substrate. An insulating layer structure and interconnections may be formed on the transistors and the photodiodes. Subsequently, a color filter including red, green and blue color filters may be formed on the insulating layer structure. A positive-type photoresist film may be coated on the color filter, thereby forming a planarization layer. After that, a photoresist film may be coated on the planarization layer, and a reflow process may then be performed, thereby forming micro-lenses for providing light guided toward the photodiodes.

However, when forming the micro-lenses by patterning the photoresist film as described above, a gap of about 100 to 200 nm may be formed between the micro-lenses, and light may be incident through the gap. Therefore, a quality of an image may be greatly degraded.

### SUMMARY

Embodiment relate to an image sensor and a method of manufacturing the same. Embodiments may provide an image sensor for enhancing the quality of images by removing a gap between micro-lenses and a method of manufacturing the image sensor.

According to embodiments, an image sensor may include a photodiode structure including a plurality of pixels, aligned on a semiconductor substrate, an inorganic micro-lens group including an inorganic substance, aligned at positions corresponding to a first pixel group in the pixels on the photodiode structure, and an organic micro-lens group including an organic substance, aligned at positions corresponding to a second pixel group except for the inorganic micro-lens group in the pixels on the photodiode structure.

According to embodiments, a method of manufacturing an image sensor may include forming a photodiode structure including a plurality of pixels on a semiconductor substrate, forming an oxide layer on the photodiode structure, patterning the oxide layer, thereby forming a first micro-lens group at positions corresponding to a first pixel group in the pixels, forming a photoresist film on the photodiode structure, and patterning the photoresist film, thereby forming a second micro-lens group at positions corresponding to a second pixel group except for the first micro-lens group in the pixels.

### DRAWINGS

FIG. 1 is a cross-sectional view of an image sensor according to embodiments.

FIG. 2 is a plan view of one of pixels included in a photodiode structure illustrated in FIG. 1.

FIG. 3 is a cross-sectional view of a photodiode structure in an image sensor according to embodiments.

FIG. 4 is a cross-sectional view illustrating forming an oxide layer on the photodiode structure illustrated in FIG. 3.

FIG. 5 is a cross-sectional view illustrating patterning the oxide layer illustrated in FIG. 4, thereby forming an inorganic micro-lens group.

FIG. 6 is a cross-sectional view illustrating forming and patterning a photoresist film on a planarization layer illustrated in FIG. 5.

FIG. 7 is a cross-sectional view illustrating preliminary micro-lenses formed by patterning the photodiode film illustrated in FIG. 6.

### DESCRIPTION

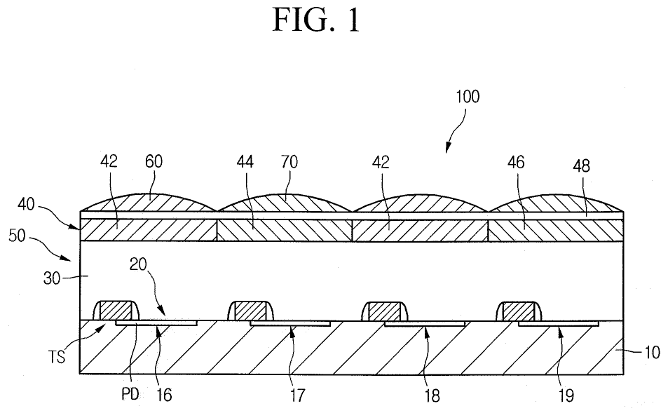

FIG. 1 is a cross-sectional view of an image sensor according to embodiments.

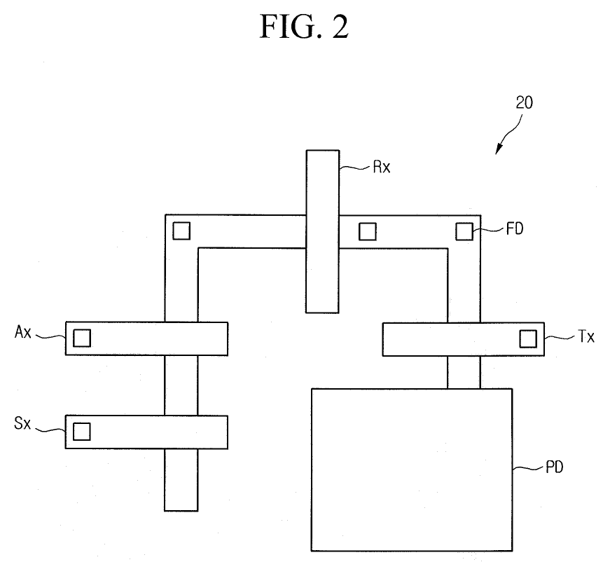

Referring to FIGS. 1 and 2, image sensor 100 may include semiconductor substrate 10, photodiode structure 50, inorganic micro-lens group 60, and organic micro-lens group 70.

Photodiode structure 50 may be positioned on semiconductor substrate 10. In embodiments, photodiode structure 50 may include a plurality of pixels 20, an insulating layer structure 30, a color filter 40, and a planarization layer 48.

Plurality of pixels 20 may be formed on semiconductor substrate 10. In FIG. 1, four pixels 20 are illustrated as an example. Hereinafter, the four pixels 20 will be defined as first, second third and fourth pixels 16, 17, 18 and 19. Further, first and third pixels 16 and 18 may constitute a first pixel group, and second and fourth pixels 17 and 19 may constitute a second pixel group.

In embodiments, the number of pixels in the first pixel group may be a half of the total number of pixels 20 as an example. In embodiments, the number of pixels in the first pixel group may not necessarily be half of the total number of pixels 20, and the number of pixels in the pixel groups may vary.

FIG. 2 is a plan view of one of pixels included in a photodiode structure illustrated in FIG. 1.

Referring to FIG. 2, pixel 20 may include photodiode PD and transistor structure (TS).

Transistor structure (TS) may include transfer transistor Tx, reset transistor Rx, select transistor Sx, and access transistor Ax.

In photodiode PD, transfer and reset transistors Tx and Rx may be connected in series. A source of transfer transistor Tx may be connected to photodiode PD, and a drain of transfer transistor Tx may be connected to a source of reset transistor Rx. A power source voltage Vdd may be applied to a drain of reset transistor Rx.

The drain of transfer transistor Tx may serve as floating diffusion (FD). Floating diffusion FD may be connected to a gate of select transistor Sx. The select and access transistors Sx and Ax may be connected in series. That is, the source of select transistor Sx and the drain of access transistor Ax may be connected to each other. Power source voltage Vdd may be applied to the drain of access transistor Ax and the source of reset transistor Rx. A drain of select transistor Sx may correspond to an output terminal OUT, and a selection signal may be applied to a gate of select transistor Sx.

An operation of pixel 20 of photodiode structure 50 in image sensor 100 according to embodiments will be briefly described below.

First, reset transistor Rx may be turned on to allow the potential of floating diffusion FD to be identical with power source voltage Vdd, and reset transistor Rx may then be turned off. Such an operation may be defined as a reset operation.

When external light is incident on photodiode PD, electron-hole pairs may be produced in the photodiode such that signal charges may be accumulated in photodiode PD. Subsequently, if transfer transistor Tx is turned on, the signal charges accumulated in the photodiode may be output to floating diffusion FD and may be stored in floating diffusion FD.

Accordingly, the potential of floating diffusion FD may be changed in proportion to an amount of the signal charges output from photodiode PD, and therefore the potential of a gate of access transistor Ax may be changed. According to embodiments, if select transistor Sx may be turned on by a selection signal, data may be output to an output terminal OUT.

After the data may be output, a reset operation may be again performed in pixel 20. The respective pixels 20 constituting photodiode structure 50 repeatedly perform the aforementioned processes such that light may be converted into an electric signal, thereby outputting an image.

Referring back to FIG. 1, insulating layer structure 30 may be formed on pixels 20 aligned on semiconductor substrate 10. An interconnection structure (not shown) for driving pixels 20 may be formed in insulating layer structure 30.

Color filter 40 may be aligned on insulating layer structure 30. Color filter 40 may include green, red and blue color filters 42, 44 and 46. In embodiments, green color filters 42 may be aligned on first and third pixels 16 and 18, red color filter 44 may be aligned on second pixel 17, and blue color filter 46 may be aligned on fourth pixel 19.

Planarization layer 48 may be formed on color filter 40. If a step difference is formed between color filters 40, planarization layer 48 may function to remove the step difference.

Inorganic and organic micro-lens groups 60 and 70 may be formed on planarization layer 48 in photodiode structure 50 including pixels 20, insulating layer structure 30, color filter 40 and planarization layer 48.

In embodiments, inorganic micro-lens group 60, for example, may be aligned on first pixel group 16 and 18 defined above. Inorganic micro-lens group 60 may include an inorganic substance. Specifically, inorganic micro-lens group 60 may be a low temperature oxidation layer formed through an LPCVD process at about 400° C. to 450° C.

Organic micro-lens group 70, for example, may be aligned on second pixel group 17 and 19 defined above. Organic micro-lens group 70 may include an organic substance. In embodiments, organic micro-lens group 70 may include a photoresist substance.

In embodiments, inorganic and organic micro-lens groups 60 and 70 may be aligned together on planarization layer 48, so that a gap between inorganic and organic micro-lens groups 60 and 70 may be removed. This may be because the inorganic micro-lens group 60 may be formed through a thin film patterning process, and the organic micro-lens group 70 may be formed through a reflow process.

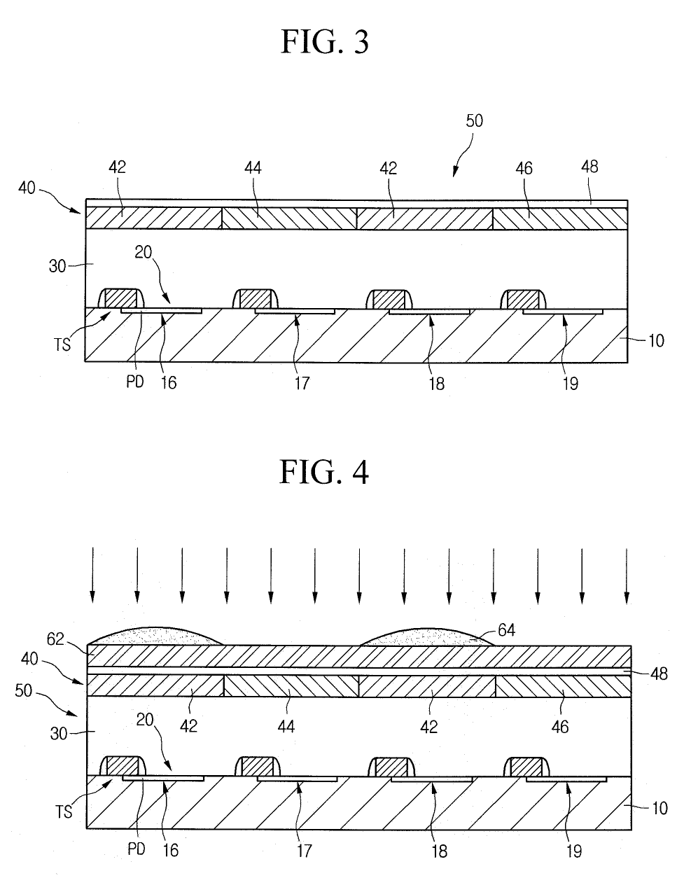

FIG. 3 is a cross-sectional view of a photodiode structure in an image sensor according to embodiments.

Referring to FIG. 3, photodiode structure 50 may be formed on semiconductor substrate 10.

To form photodiode structure 50, transistor structure TS, which may include 3 to 5 transistors, and pixels 20 each having a photodiode PD may be formed on semiconductor substrate 10. Hereinafter, pixels 20 illustrated in FIG. 1 in plurality of pixels 20 formed on semiconductor substrate 10 may be defined as first to fourth pixels 16, 17, 18 and 19. Further, first and third pixels 16 and 18 constitute a first pixel group, and second and fourth pixels 17 and 19 constitute a second pixel group.

After forming pixels 20 on semiconductor substrate 10, insulating structure 30 may be formed on semiconductor substrate 10. Insulating layer structure 30 may function to cover and insulate pixels 20. While forming insulating layer structure 30, an interconnection structure (not shown) for driving the pixels may be formed in insulating layer structure 30.

After forming insulating layer structure 30, color filter 40 may be formed on insulating layer structure 30. Color filter 40 may be formed by patterning a photoresist film including a pigment or dye and a photoresist. Color filter 40 may include green, red and blue color filters 42, 44 and 46. Green color filter 42 may be formed on insulating layer structure 30 corresponding to first pixel group, and red and blue color filters 44 and 46 may be formed on insulating layer structure 30 corresponding to second pixel group.

After forming color filter 40, planarization layer 48 may be formed on color filter 40, thereby manufacturing photodiode structure 50. If a step difference is formed between color filters 40, planarization layer 48 may function to remove the step difference.

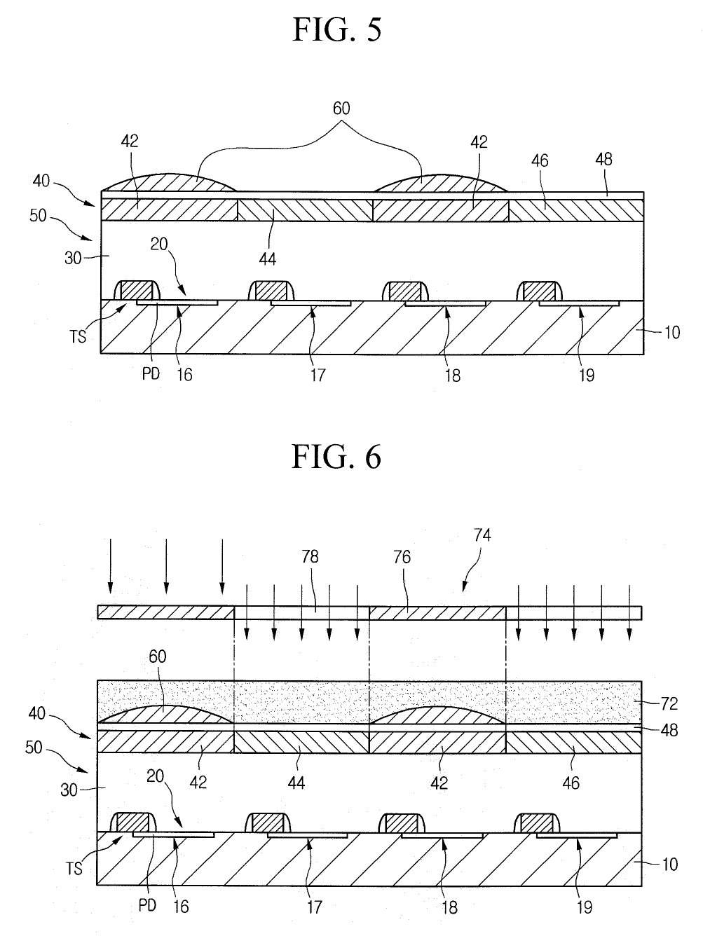

FIG. 4 is a cross-sectional view illustrating forming an oxide layer on the photodiode structure illustrated in FIG. 3. FIG. 5 is a cross-sectional view illustrating patterning the oxide layer illustrated in FIG. 4, thereby forming an inorganic micro-lens group.

Referring to FIGS. 4 and 5, after forming photodiode structure 50, oxide layer 62 may be formed on planarization layer 48. In embodiments, oxide layer 62 may be a low temperature oxidation (LTO) layer formed through an LPCVD process at 400° C. to 450° C.

After forming oxide layer 62, a photoresist film (not shown) may be formed on oxide layer 62, for example through a spin coating process or the like. After that, the photoresist film may be patterned, thereby forming sacrifice micro-lens patterns 64 on oxide layer 62. In embodiments, sacrifice micro-lens patterns 64 may be formed, for example, on first pixel group 16 and 18.

Subsequently, oxide layer 62 may be etched through an etchback process using sacrifice micro-lens patterns 64 as an etching mask, thereby forming inorganic micro-lens patterns 60 corresponding to first pixel group 16 and 18 as illustrated in FIG. 5.

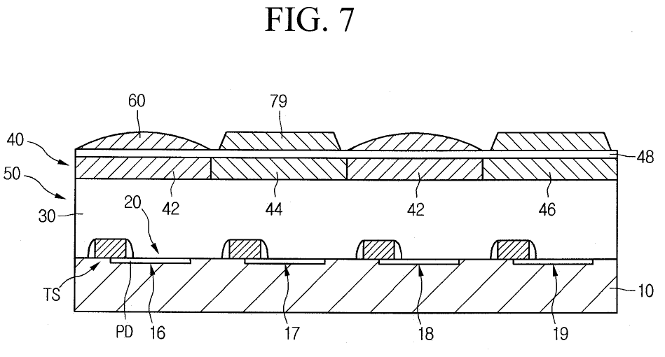

FIG. 6 is a cross-sectional view illustrating forming and patterning a photoresist film on the planarization layer illustrated in FIG. 5. FIG. 7 is a cross-sectional view illustrating preliminary micro-lenses formed by patterning the photodiode film illustrated in FIG. 6.

Referring to FIG. 6, photoresist film 72 may be formed on a surface (for example, the entire surface) of planarization layer 48 having inorganic micro-lens patterns 60. Photoresist film 72 may be formed, for example, through a spin coating process or the like. In embodiments, photoresist film 72 may include, for example, a positive-type photoresist material.

After forming photoresist film 72, reticle 74 may be aligned on photoresist film 72. Reticle 74 may include light absorbing portions 76 and light transmitting portions 78. Light absorbing portions 76 may be formed at positions corresponding to first pixel group 16 and 18 having inorganic micro-lens patterns 60. Light transmitting portions 78 may be formed at positions corresponding to second pixel group 17 and 19 having no inorganic micro-lens pattern 60.

After aligning reticle 74 on photoresist film 72, photoresist film 72 may be exposed using reticle 74, thereby exposing photoresist film 72 corresponding to the light transmitting portions 78. After that, the exposed photoresist film 72 may be developed using a developing solution, and may thereby form preliminary micro-lenses 79 on planarization layer 48 as illustrated in FIG. 7.

Preliminary micro-lenses 79 may be changed into organic micro-lenses 70 through a reflow process as illustrated in FIG. 1. In embodiments, organic micro-lenses 70 may be formed at positions corresponding to the second pixel group 17 and 19.

When reflowing the preliminary micro-lenses 79, the preliminary micro-lenses 79 may flow and may come into contact with edges of inorganic micro-lenses 60. For this reason, a gap may be not formed between inorganic and organic micro-lenses 60 and 70.

As described above, an inorganic layer including an inorganic substance may be patterned to form an inorganic micro-lens, and an organic layer including an organic substance may be patterned to form an organic micro-lens through a reflow process, thereby removing a gap between the inorganic and organic micro-lenses. Accordingly, the quality of an image produced by an image sensor may be enhanced.

It will be apparent to those skilled in the art that various modifications and variations can be made to embodiments. Thus, it is intended that embodiments cover modifications and variations thereof within the scope of the appended claims. It is also understood that when a layer is referred to as being “on” or “over” another layer or substrate, it can be directly on the other layer or substrate, or intervening layers may also be present.

What is claimed is:

1. A device, comprising:
a photodiode structure including a plurality of pixels aligned over a semiconductor substrate;
an inorganic micro-lens group comprising an inorganic substance and aligned at positions corresponding to pixels of a first pixel group of the plurality of pixels over the photodiode structure; and
an organic micro-lens group comprising an organic substance and aligned at positions corresponding to pixels of a second pixel group of the plurality of pixels over the photodiode structure.

2. The device of claim 1, wherein the first pixel group and the second pixel group have no pixels in common.

3. The device of claim 1, wherein the inorganic micro-lens group comprises a low temperature oxidation layer formed at a temperature of 400° C. to 450° C.

4. The device of claim 1, wherein the organic micro-lens group comprises a photosensitive material.

5. The device of claim 1, wherein a number of pixels comprising the first pixel group is equal to half of a total number of pixels.

6. The device of claim 5, wherein the first pixel group comprises alternating pixels among the plurality of pixels.

7. The device of claim 1, wherein micro-lenses comprising the inorganic micro-lens group and micro-lenses comprising the organic micro-lens group are positioned in an alternating fashion.

8. The device of claim 7, wherein at least one of the micro-lenses comprising the organic micro-lens group contacts at least one of the micro-lenses comprising the inorganic micro-lens group and eliminates a gap between contacting lenses.

9. The device of claim 8, wherein the micro-lenses comprising the organic micro-lens group are formed through a reflow process.

10. A method, comprising:
forming a photodiode structure including a plurality of pixels over a semiconductor substrate;
forming an oxide layer over the photodiode structure;
patterning the oxide layer, to form a first micro-lens group at positions corresponding to a first pixel group of the plurality of pixels;
forming a photoresist film over the photodiode structure; and
patterning the photoresist film, to form a second micro-lens group at positions corresponding to a second pixel group of remaining pixels not in the first pixel group.

11. The method of claim 10, wherein forming the oxide layer comprises performing an LPCVD process at 400° C. to 450° C.

12. The method of claim 10, wherein forming the first micro-lens group comprises:
forming a photoresist film over the oxide layer;
pattering the photoresist film, to form sacrifice micro-lens patterns; and
patterning the oxide layer using the sacrifice micro-lens patterns as an etching mask.

13. The method of claim 10, wherein forming the second micro-lens group comprises:
patterning the photoresist film to form preliminary micro-lenses; and
reflowing the preliminary micro-lenses such that a gap is not formed between the first and second micro-lens groups.

14. The method of claim 10, wherein at least one lens comprising the first micro-lens group is positioned between lenses comprising the second micro-lens group.

15. The method of claim 10, wherein a number of lenses comprising the first micro-lens group is equal to a number of lenses comprising the second micro-lens group.

16. A device, comprising:
a first photodiode over a semiconductor substrate;
a second photodiode over the semiconductor substrate positioned adjacent to the first photodiode;
a first inorganic micro-lens over the first photodiode; and
a first organic micro-lens over the second photodiode.

17. The device of claim 16, wherein the first inorganic micro-lens and the first organic micro-lens are in contact with each other.

18. The device of claim 17, wherein the first organic micro-lens is formed through a reflow process.

19. The device of claim 17, further comprising:
a third photodiode adjacent to the second photodiode and a fourth photodiode in adjacent to the third photodiode; and
a second inorganic micro-lens over the third photodiode and a second organic micro-lens over the fourth photodiode, the second inorganic micro-lens being in contact with the first organic micro-lens, and the second organic micro-lens being in contact with the second inorganic micro-lens, such that there are no gaps between adjacent micro-lenses.

20. The device of claim 17, wherein the first inorganic micro-lens comprises a low temperature oxidation layer formed at a temperature of approximately 400° C. to 450° C.
